(19) United States
(12) Patent Application Publication
(10) Pub. No.: US 2025/0046705 A1
(43) Pub. Date: Feb. 6, 2025

(54) SEMICONDUCTOR DEVICE AND METHOD OF MANUFACTURING THE SAME

(71) Applicant: Renesas Electronics Corporation, Tokyo (JP)

(72) Inventors: Nobuhito SHIRAISHI, Tokyo (JP); Yorinobu KUNIMUNE, Tokyo (JP); Yoshimi KATO, Tokyo (JP); Nozomi ITO, Tokyo (JP); Mengnan YANG, Tokyo (JP); Kenichiro SONODA, Tokyo (JP)

(21) Appl. No.: 18/769,072

(22) Filed: Jul. 10, 2024

(30) Foreign Application Priority Data
Jul. 31, 2023 (JP) 2023-124526

(51) Int. Cl. H01L 23/522; H01L 21/02; H01L 21/768; H01L 23/532

(52) U.S. Cl. CPC H01L 23/5228; H01L 21/02063; H01L 21/76883; H01L 23/53209; H01L 23/53271; H01L 23/53276; H01L 28/22; H01L 28/24

(57) ABSTRACT

A semiconductor device includes a first dielectric film, a resistor element disposed on the first dielectric film, and a second dielectric film disposed on the resistor element. The resistor element contains silicon, chromium, and carbon. The silicon concentration in the resistor element increases from a center part of the resistor element towards an upper surface of the resistor element, and also increases from the center part of the resistor element towards a lower surface of the resistor element.

### CROSS-REFERENCE TO RELATED APPLICATIONS

The disclosure of Japanese Patent Application No. 2023-124526 filed on Jul. 31, 2023, including the specification, drawings and abstract is incorporated herein by reference in its entirety.

### BACKGROUND

The present invention relates to a semiconductor device and a method for manufacturing the same, and can be suitably used, for example, for a semiconductor device including a resistive element and a method for manufacturing the same.

There are disclosed techniques listed below.
[Patent Document 1] Japanese Unexamined Patent Application Publication No. 2023-56630
[Patent Document 2] Japanese Unexamined Patent Application Publication No. 2023-58091

Patent Document 1 and Patent Document 2 disclose a semiconductor device including a resistor element containing silicon, chromium, and carbon.

### SUMMARY

In a semiconductor device including a resistor element containing silicon, chromium, and carbon, it is desirable to improve performance.

Other objects and novel features will become apparent from the description of this specification and the accompanying drawings.

According to one embodiment, a semiconductor device includes a first dielectric film, a resistor element disposed on the first dielectric film, and a second dielectric film disposed on the resistor element. The resistor element contains silicon, chromium, and carbon. A silicon concentration of the resistor element increases from a center part of the resistor element toward the upper surface of the resistor element, and increases from the center part of the resistor element toward the lower surface of the resistor element.

According to one embodiment, the performance of the semiconductor device can be improved.

### BRIEF DESCRIPTION OF THE DRAWINGS

FIG. 1 is a main portion cross-sectional view of a semiconductor device of a first embodiment.

FIG. 2 is a main portion cross-sectional view during a manufacturing step of the semiconductor device of the first embodiment.

FIG. 3 is a main portion cross-sectional view during the manufacturing step of the semiconductor device following FIG. 2.

FIG. 4 is a main portion cross-sectional view during the manufacturing step of the semiconductor device following FIG. 3.

FIG. 5 is a main portion cross-sectional view during the manufacturing step of the semiconductor device following FIG. 4.

FIG. 6 is a main portion cross-sectional view during the manufacturing step of the semiconductor device following FIG. 5.

FIG. 7 is a main portion cross-sectional view during the manufacturing step of the semiconductor device following FIG. 6.

FIG. 8 is a main portion cross-sectional view during the manufacturing step of the semiconductor device following FIG. 7.

FIG. 9 is a main portion cross-sectional view during the manufacturing step of the semiconductor device following FIG. 8.

FIG. 10 is a main portion cross-sectional view during the manufacturing step of the semiconductor device following FIG. 9.

FIG. 11 is a main portion cross-sectional view during the manufacturing step of the semiconductor device following FIG. 10.

FIG. 12 is a main portion cross-sectional view during the manufacturing step of the semiconductor device following FIG. 11.

FIG. 13 is a main portion cross-sectional view during the manufacturing step of the semiconductor device following FIG. 12.

FIG. 14 is a graph showing the resistivity and temperature coefficient of resistance of the Si—Cr—C resistor element.

FIG. 15 is a graph showing the relationship between the annealing temperature and the resistivity and temperature coefficient of resistance.

FIG. 16 is a partial enlarged cross-sectional view of a semiconductor device of an examined example.

FIG. 17 is a partial enlarged cross-sectional view of the semiconductor device of the examined example.

FIG. 18 is a partial enlarged cross-sectional view of FIG. 1.

FIG. 19 is a graph showing the concentration distribution of silicon, chromium, and carbon in the laminated structure shown in FIG. 18.

FIG. 20 is a graph showing the results of analyzing the concentration distribution of silicon, chromium, and carbon when no crystallization annealing treatment is performed.

FIG. 21 is a graph showing the correlation between the annealing temperature and the temperature coefficient of resistance.

FIG. 22 is a plan view of the resistor element.

FIG. 23 is a cross-sectional view of the resistor element.

FIG. 24 is a graph showing the correlation between the width of the resistor element and the resistance value.

FIG. 25 is a graph showing the correlation between the width of the resistor element and the temperature coefficient of resistance.

FIG. 26 is a plan view of a resistor element of a modified example.

FIG. 27 is a cross-sectional view of the resistor element of the modified example.

FIG. 28 is a cross-sectional view of the resistor element of the modified example.

FIG. 29 is a main portion cross-sectional view during a manufacturing step of a semiconductor device of a second embodiment.

FIG. 30 is a main portion cross-sectional view during the manufacturing step of the semiconductor device following FIG. 29.

FIG. 31 is a main portion cross-sectional view during the manufacturing step of the semiconductor device following FIG. 30.

FIG. 32 is a main portion cross-sectional view during the manufacturing step of the semiconductor device following FIG. 31.

FIG. 33 is a main portion cross-sectional view during the manufacturing step of the semiconductor device following FIG. 32.

FIG. 34 is a cross-sectional view of the resistor element.

FIG. 35 is a graph showing the carbon content rate and the temperature coefficient of resistance of the resistor element.

### DETAILED DESCRIPTION

In the following embodiments, when required for convenience, the description will be made by dividing into a plurality of sections or embodiments, but except when specifically stated, they are not independent of each other, and one is related to the modified example, detail, supplementary description, or the like of part or all of the other. In the following embodiments, the number of elements, etc. (including the number of elements, numerical values, quantities, ranges, etc.) is not limited to the specific number, but may be not less than or equal to the specific number, except for cases where the number is specifically indicated and is clearly limited to the specific number in principle. Furthermore, in the following embodiments, it is needless to say that the constituent elements (including element steps and the like) are not necessarily essential except in the case where they are specifically specified and the case where they are considered to be obviously essential in principle. Similarly, in the following embodiments, when referring to the shapes, positional relationships, and the like of components and the like, it is assumed that the shapes and the like are substantially approximate to or similar to the shapes and the like, except for the case in which they are specifically specified and the case in which they are considered to be obvious in principle, and the like. The same applies to the above numerical values and ranges.

Hereinafter, embodiments are described in detail with reference to the drawings. In all the FIGS. for explaining the embodiments, the same reference numerals are given to the members having the same functions, and the description of the repetition is omitted. Also, in the following embodiments, descriptions of the same or similar parts will not be repeated in principle except when particularly necessary.

In the drawings used in the embodiments, hatching may be omitted even in the case of cross-sectional view in order to make the drawings easier to see. Also, even in the case of a plan view, hatching may be used to make the drawing easier to see.

### FIRST EMBODIMENT

### Structure of Semiconductor Device

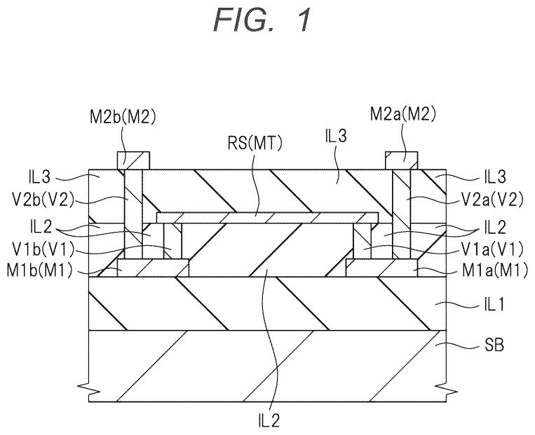

The semiconductor device of the present embodiment will be described with reference to the drawings. FIG. 1 is a main portion cross-sectional view of the semiconductor device according to the present embodiment.

As shown in FIG. 1, the semiconductor device of the present embodiment includes a semiconductor substrate SB, a dielectric film IL1, a dielectric film IL2, a dielectric film IL3, a plurality of wirings M1, a plurality of wirings M2, a plurality of plugs V1, a plurality of plugs V2, and a resistor element RS.

The dielectric film IL1 is formed on a main surface of the semiconductor substrate SB. The plurality of wirings Ml are formed on the dielectric film IL1 so as to contact an upper surface of the dielectric film IL1. The dielectric film IL2 is formed on the dielectric film IL1 so as to cover the plurality of wirings M1. The resistor element RS is formed on the dielectric film IL2 so as to contact an upper surface of the dielectric film IL2. The dielectric film IL3 is formed on the dielectric film IL2 so as to cover the resistor element RS. The upper surface and side surface of the resistor element RS contact the dielectric film IL3. The lower surface of the resistor element RS contacts the dielectric film IL2.

The plurality of wirings M2 are formed on the dielectric film IL3 so as to contact the upper surface of the dielectric film IL3. Each of the plurality of plugs V1 has conductivity. Each of the plurality of plugs V2 has conductivity. Each of the plurality of plugs V1 is disposed in the dielectric film IL2.

Specifically, each of the plurality of plugs V1 is buried in an opening that penetrates through the dielectric film IL2. Each of the plurality of plugs V2 is buried in an opening that penetrates through the dielectric films IL2, IL3.

Each of the dielectric films IL1, IL2, IL3 is a single-layer dielectric film or a laminated dielectric film. The laminated dielectric film f is a laminated film in which a plurality of dielectric films are laminated.

The resistor element RS contains silicon (Si), chromium (Cr), and carbon (C) as constituent elements. Specifically, the resistor element RS is made of a material layer (resistor layer)

MT that contains silicon (Si), chromium (Cr), and carbon (C) as constituent elements. The planar shape of the material layer MT is, for example, rectangular. A thickness of the material layer MT is preferably 10 nm or less, and more preferably, 2 nm or more and 10 nm or less.

The plurality of plugs V1 include a plug V1a and a plug V1b. The plurality of plugs V2 include a plug V2a and a plug V2b. The plurality of wirings M1 include a wiring M1a and a wiring M1b. The plurality of wirings M2 include a wiring M2a and a wiring M2b. The wiring M1a and the wiring M1b are spaced apart from each other. The wiring M2a and the wiring M2b are spaced apart from each other.

The wiring M1a and the wiring M1b are disposed on the dielectric film IL1 so as to be covered by the dielectric film IL2. The plug V1a is disposed in the dielectric film IL2 and is connected to the wiring M1a. The plug V1b is disposed in the dielectric film IL2 and is connected to the wiring M1b. The resistor element RS connects the plug V1a and the plug V1b.

Specifically, in the vicinity of one end of the material layer MT, the upper surface of the plug V1a is covered by the material layer MT and contacts the lower surface of the material layer MT. The plug V1a is electrically connected to the material layer MT. The plug V1a is disposed on the wiring M1a, and the lower surface of the plug V1a contacts the upper surface of the wiring M1a. The plug V1a is electrically connected to the wiring M1a.

The plug V2a is disposed on the wiring M1a, and the lower surface of the plug V2a contacts the upper surface of the wiring M1a. The plug V2a is electrically connected to the wiring M1a. The upper surface of the plug V2a is covered by the wiring M2a and contacts the lower surface of the wiring M2a. The plug V2a is electrically connected to the wiring M2a.

In the vicinity of the other end of the material layer MT, the upper surface of the plug V1b is covered by the material layer MT and contacts the lower surface of the material layer MT. The plug V1b is electrically connected to the material layer MT. The plug V1b is disposed on the wiring M1b, and the lower surface of the plug V1b contacts the upper surface of the wiring M1b. The plug V1b is electrically connected to the wiring M1b.

The plug V2b is disposed on the wiring M1b, and the lower surface of the plug V2b contacts the upper surface of the wiring M1b. The plug V2b is electrically connected to the wiring M1b. The upper surface of the plug V2b is covered by the wiring M2b and contacts the lower surface of the wiring M2b. The plug V2b is electrically connected to the wiring M2b.

Therefore, one end of the resistor element RS is connected to the plug V1a, and the other end of the resistor element RS is connected to the plug V1b. The wiring M2a is electrically connected to one end of the resistor element RS via the plug V2a, the wiring M1a, and the plug V1a. The wiring M2b is electrically connected to the other end of the resistor element RS via the plug V2b, the wiring M1b, and the plug V1b.

The illustration and description of the structure above the dielectric film IL3 and the wiring M2 are omitted.

### Manufacturing Steps of Semiconductor Device

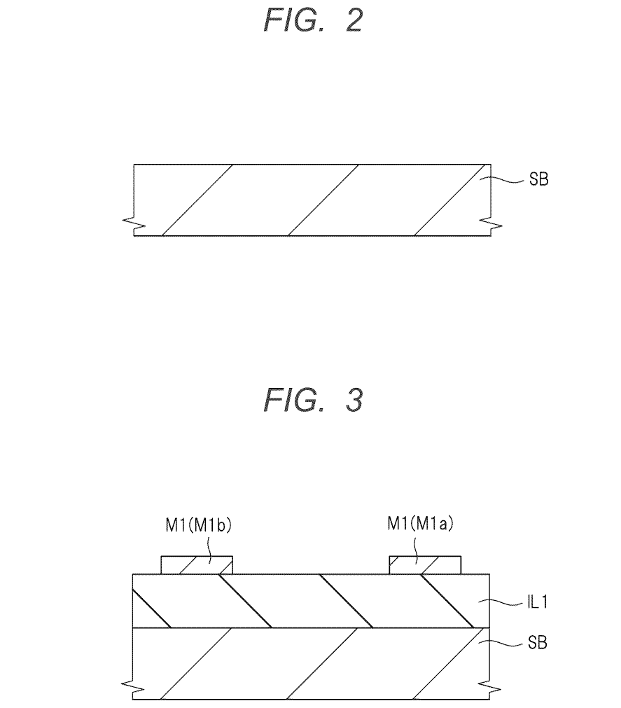

The manufacturing steps of the semiconductor device of the present embodiment is explained with reference to the drawings. FIGS. 2 to 13 are main portion cross-sectional views during the manufacturing steps of the semiconductor device of the present embodiment.

First, as shown in FIG. 2, the semiconductor substrate SB is prepared. The semiconductor substrate SB is made of, for example, monocrystalline silicon into which p-type or n-type impurities are introduced.

Next, if necessary, semiconductor elements such as MISFET (Metal Insulator Semiconductor Field Effect Transistor) or diodes (not shown) are formed on the semiconductor substrate SB. Next, as shown in FIG. 3, the dielectric film IL1 is formed on the main surface of the semiconductor substrate SB. The dielectric film IL1 is an interlayer dielectric film. The dielectric film IL1 can be made of, for example, a silicon oxide film and can be formed using a method such as CVD (Chemical Vapor Deposition) method. After forming the dielectric film IL1, the upper surface of the dielectric film IL1 can also be planarized using a method such as CMP (Chemical Mechanical Polishing) method.

Next, as shown in FIG. 3, the plurality of wirings Ml are formed on the dielectric film IL1. For example, a conductive film is formed on the dielectric film IL1. After that, by patterning the conductive film using photolithography technique and etching technique, the plurality of wirings M1 made of the conductive film can be formed. The plurality of wirings M1 are, for example, aluminum wirings, but wirings using other metal materials can also be applied. The plurality of wirings M1 include the wiring M1a and the wiring M1b.

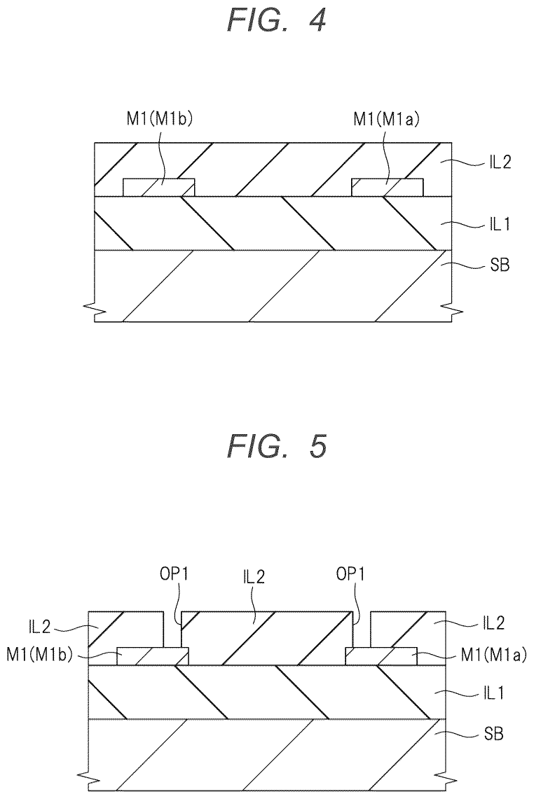

Next, as shown in FIG. 4, the dielectric film IL2 is formed on the dielectric film IL1 so as to cover the plurality of wirings M1. The dielectric film IL2 is an interlayer dielectric film. The dielectric film IL2 is made of, for example, a silicon oxide film. After forming the dielectric film IL2, the upper surface of the dielectric film IL2 can be planarized using a CMP method or the like.

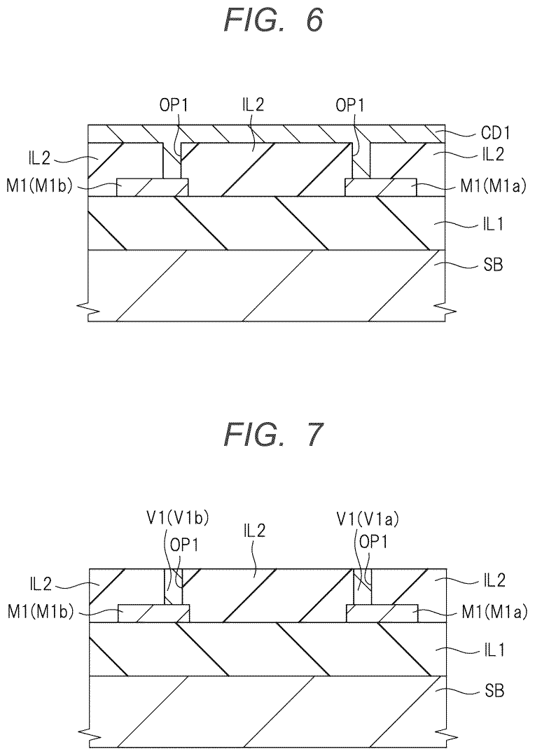

Next, as shown in FIG. 5, a plurality of openings OP1 penetrating through the dielectric film IL2 are formed by etching the dielectric film IL2 using a photoresist pattern (not shown) formed on the dielectric film IL2 as an etching mask. Next, as shown in FIG. 6, a conductive film CD1 is formed on the dielectric film IL2 so as to fill the plurality of openings OP1 in the dielectric film IL2. The conductive film CD1 is, for example, a laminated film configured by a barrier conductive film and a main conductive film on the barrier conductive film. The main conductive film is, for example, a tungsten film. Then, as shown in FIG. 7, the conductive film CD1 disposed outside the plurality of openings OP1 in the dielectric film IL2 is removed by a CMP method or the like. As a result, the plurality of plugs V1 are formed. The plurality of plugs V1 are each buried in the plurality of openings OP1. The plurality of plugs V1 include the plug V1a and the plug V1b.

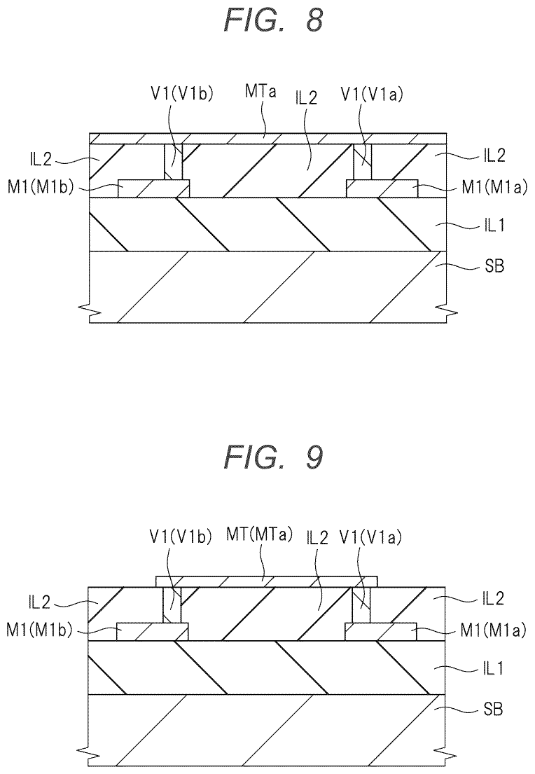

Next, as shown in FIG. 8, a material layer MTa is formed on the dielectric film IL2 so as to cover the upper surface of each plug V1, using a sputtering method or the like. The material layer MTa is formed on the entire upper surface of the dielectric film IL2 and on the upper surface of the plurality of plugs V1. The material layer MTa contains silicon (Si), chromium (Cr), and carbon (C) as constituent elements. The material layer MTa is an amorphous film.

Next, as shown in FIG. 9, the material layer MT is formed by patterning the material layer MTa using photolithography technique and etching technique. The material layer MT is made of the patterned material layer MTa. The material layer MT configures the resistor element RS.

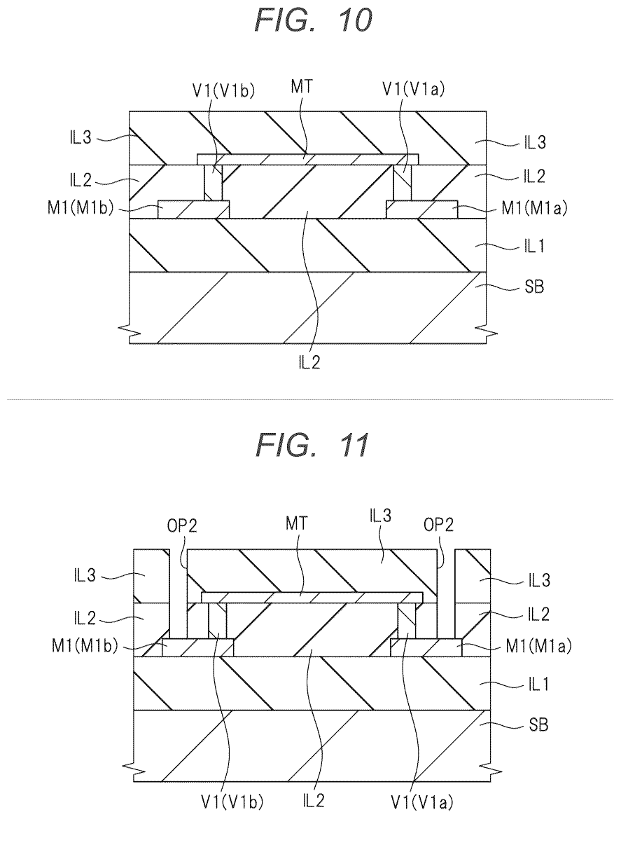

Next, as shown in FIG. 10, the dielectric film IL3 is formed on the dielectric film IL2 so as to cover the material layer MT. The dielectric film IL3 is an interlayer dielectric film. The dielectric film IL3 is made of, for example, a silicon oxide film. The dielectric film IL3 is formed so as to contact the upper surface and side surface of the material layer MT. After forming the dielectric film IL3, the upper surface of the dielectric film IL3 can be planarized using a CMP method or the like.

Next, a heat treatment (annealing treatment) is performed to crystallize the material layer MT. By this heat treatment, the material layer MT is heated, and a part or all of the amorphous material layer MT is crystallized.

Next, as shown in FIG. 11, a plurality of openings OP2 penetrating through the dielectric films IL3 and IL2 are formed by etching the dielectric films IL3 and IL2 using a photoresist pattern (not shown) formed on the dielectric film IL3 as an etching mask.

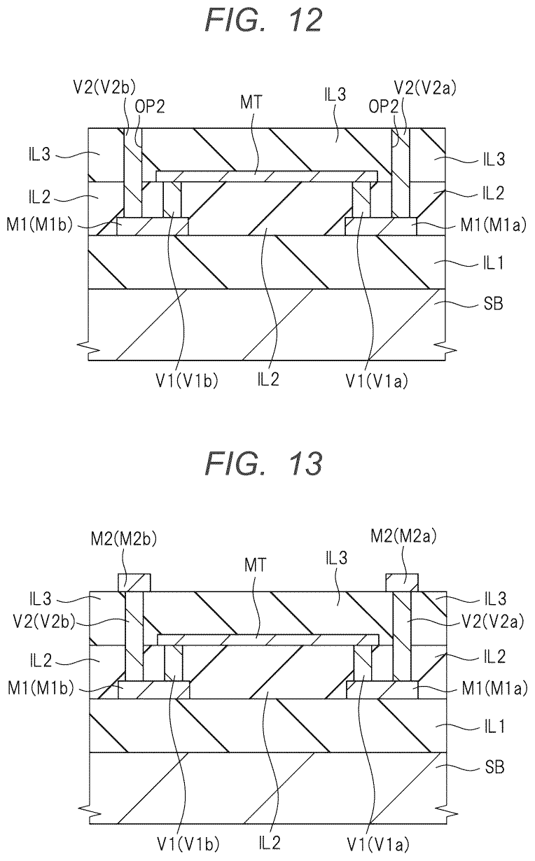

Next, as shown in FIG. 12, the plurality of plugs V2 are formed. For example, a conductive film is formed on the dielectric film IL3 so as to fill the plurality of openings OP2. This conductive film is, for example, a laminated film configured by a barrier conductive film and a main conductive film on the barrier conductive film. The main conductive film is, for example, a tungsten film. Then, the conductive film disposed outside the plurality of openings OP2 is removed by a CMP method or the like. As a result, the plurality of plugs V2 are formed. The plurality of plugs V2 are each buried in the plurality of openings OP2. The plurality of plugs V2 include the plug V2a and the plug V2b. Next, as shown in FIG. 13, the plurality of wirings M2 are formed on the dielectric film IL3. For example, a conductive film is formed on the dielectric film IL1. Then, the plurality of wirings M2 made of the conductive film can be formed by patterning the conductive film using photolithography technique and etching technique. The plurality of wirings M2, for example, are made of aluminum wiring, but other metal material wirings can also be applied. The plurality of wirings M2 include the wiring M2a and the wiring M2b.

The illustration and explanation of the step of forming a further upper layer dielectric film and wiring are omitted.

### Background of Study

The present inventor is studying a resistor element containing silicon (Si), chromium (Cr), and carbon (C) as constituent elements. Hereinafter, a resistor element containing silicon (Si), chromium (Cr), and carbon (C) as constituent elements is referred to as a Si—Cr—C resistor element. The above-mentioned resistor element RS is also a Si—Cr—C resistor element. Also, a film containing silicon (Si), chromium (Cr), and carbon (C) as constituent elements is referred to as a Si—Cr—C film. The above-mentioned material layer MTa is also a Si—Cr—C film.

In the Si—Cr—C resistor element, it is desirable that the resistivity is high and the absolute value of the temperature coefficient of resistance (TCR) is small. If the resistivity of the resistor element is high, the resistance value can be increased while reducing the planar dimensions of the resistor element, so the semiconductor device including the resistor element can be miniaturized. If the absolute value of the temperature coefficient of resistance is small, the change in the resistance value of the resistor element due to temperature changes can be suppressed, SO the performance of the semiconductor device including the resistor element can be improved.

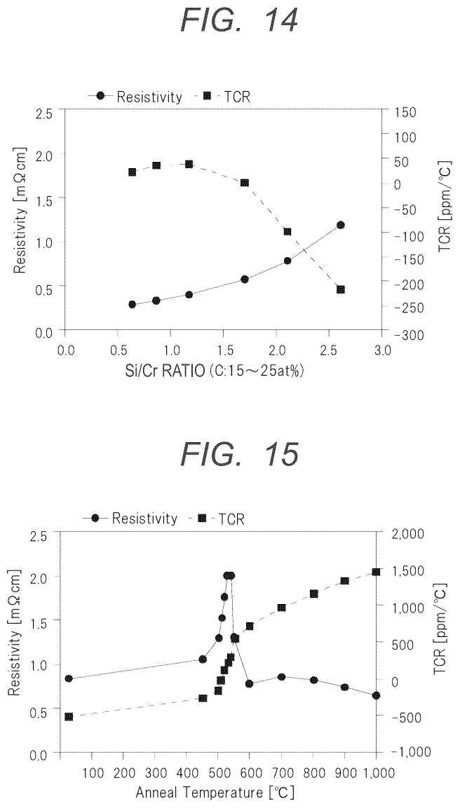

FIG. 14 is a graph showing the resistivity and temperature coefficient of resistance of the Si—Cr—C resistor element. The horizontal axis of FIG. 14 corresponds to the ratio of silicon to chromium in the Si—Cr—C resistor element based on the number of atoms. Hereinafter, the ratio of silicon to chromium in the Si—Cr—C resistor element is referred to as the Si/Cr ratio. The Si/Cr ratio is a content ratio based on the number of atoms. The vertical axis of FIG. 14 corresponds to the resistivity or temperature coefficient of resistance (TCR) of the Si—Cr—C resistor element. In FIG. 14, the resistivity and temperature coefficient of resistance of the Si—Cr—C resistor element when the Si/Cr ratio is changed are shown, and the carbon content in the Si—Cr—C resistor element is 15 to 25 atomic percent based on the number of atoms. Also, the graph in FIG. 14 is based on measurement data for the Si—Cr—C resistor element that has not undergone crystallization annealing treatment.

From the graph in FIG. 14, it can be seen that the resistivity of the Si—Cr—C resistor element increases as the Si/Cr ratio increases.

On the other hand, from the graph in FIG. 14, it can be seen that when the Si/Cr ratio exceeds 1.2, the temperature coefficient of resistance of the Si—Cr—C resistor element gradually decreases, and when the Si/Cr ratio exceeds 1.5, the temperature coefficient of resistance of the Si—Cr—C resistor element decreases even more. And when the Si/Cr ratio exceeds 2.5, the absolute value of the temperature coefficient of resistance of the Si—Cr—C resistor element increases to an undesirable level (200 ppm/degree or more) as a resistance material.

In the Si—Cr—C resistor element, the resistivity and the temperature coefficient of resistance are in a trade-off relationship. Therefore, if the resistivity increases, the absolute value of the temperature coefficient of resistance increases. Therefore, it is difficult to simply adjust the composition ratio of the Si—Cr—C resistor element to increase the resistivity and suppress the absolute value of the temperature coefficient of resistance.

FIG. 15 is a graph showing the relationship between the annealing temperature and the resistivity and temperature coefficient of resistance when a crystallization annealing treatment is applied to the Si—Cr—C resistor element. The horizontal axis of the graph in FIG. 15 corresponds to the annealing temperature. The vertical axis of the graph in FIG. 15 corresponds to the resistivity or temperature coefficient of resistance (TCR) of the Si—Cr—C resistor element.

From the graph in FIG. 15, it can be seen that the resistivity and temperature coefficient of resistance of the Si—Cr—C resistor element change by applying a crystallization annealing treatment. In the graph in FIG. 15, when the annealing temperature is in the range of 520 degrees Celsius to 530 degrees Celsius, the absolute value of the temperature coefficient of resistance is small.

However, annealing at a temperature higher than 500 degrees Celsius is not desirable. This is because annealing at a temperature higher than 500 degrees Celsius may affect the wiring or semiconductor devices formed on the semiconductor substrate. Therefore, in order to improve the reliability of the semiconductor device, it is desirable to perform a crystallization annealing treatment on the Si—Cr—C resistor element at a temperature of 500 degrees Celsius or lower.

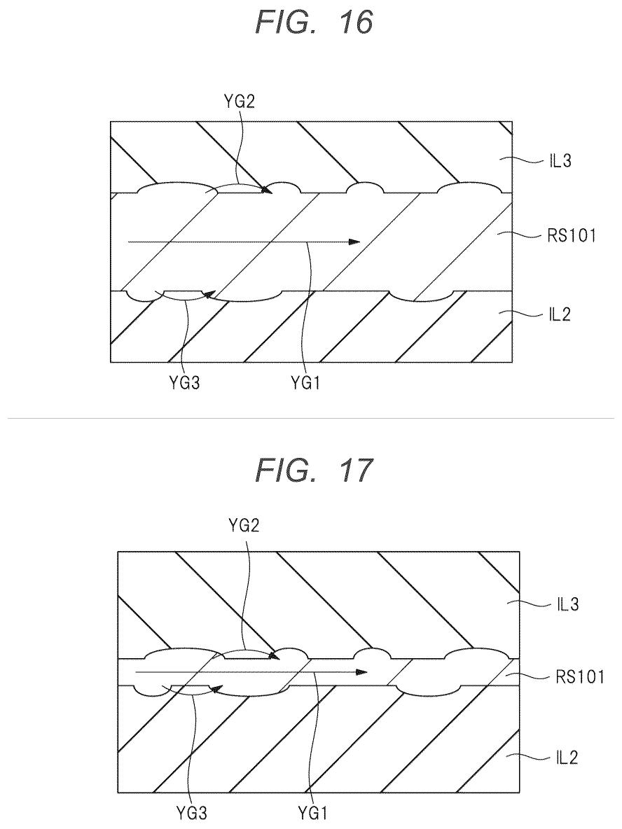

FIGS. 16 and 17 are partial enlarged cross-sectional views of a semiconductor device of an examined example studied by the present inventor.

The semiconductor device of the examined example shown in FIGS. 16 and 17 includes the dielectric film IL2, a Si—Cr—C resistor element RS101 formed on the dielectric film IL2, and the dielectric film IL3 formed on the Si—Cr—C resistor element RS101. However, FIG. 16 shows a case where a thickness of the Si—Cr—C resistor element RS101 is large, and FIG. 17 shows a case where the thickness of the Si—Cr—C resistor element RS101 is small. For example, in the case of FIG. 16, the thickness of the Si—Cr—C resistor element RS101 is about 300 nm. On the other hand, in the case of FIG. 17, the thickness of the Si—Cr—C resistor element RS101 is 10 nm or less.

The upper surface and the lower surface of the Si—Cr—C resistor element RS101 are not completely f flat, but have unevenness reflecting the surface roughness. Therefore, each of the upper surface and the lower surface of the Si—Cr—C resistor element RS101 has a plurality of protrusions (protruding portions). This is because it is difficult to form the Si—Cr—C film with completely flat upper surface and lower surface. The same applies to the upper surface and the lower surface of the resistor element RS of the present embodiment. The upper surface and the lower surface of the resistor element RS are not completely flat, but have unevenness reflecting the surface roughness. Therefore, each of the upper surface and the lower surface of the resistor element RS of the present embodiment has the plurality of protrusions (protruding portions).

When a current is passed through the Si—Cr—C resistor element RS101, electrons are conducted through the interior of the Si—Cr—C resistor element RS101. In each of FIGS. 16 and 17, the arrow YG1 indicates a conduction path passing through the interior of the Si—Cr—C resistor element RS101. However, when a current is passed through the Si—Cr—C resistor element RS101, conduction of electrons passing through the dielectric film IL2 or the dielectric film IL3 also occurs due to the unevenness on the upper surface and the lower surface of the Si—Cr—C resistor element RS101.

Specifically, in each of FIGS. 16 and 17, a current flows between the protrusions on the upper surface of the Si—Cr—C resistor element RS101 along the path schematically indicated by the arrow YG2. The arrow YG2 indicates a conduction path passing through the dielectric film IL3. Also, a current flows between the protrusions on the lower surface of the Si—Cr—C resistor element RS101 along the path schematically indicated by the arrow YG3. The arrow YG3 indicates a conduction path passing through the dielectric film IL2. That is, in the vicinity of the upper surface of the Si—Cr—C resistor element RS101, a part of the dielectric film IL3 also contributes as an electron conduction path, and in the vicinity of the lower surface of the Si—Cr—C resistor element RS101, a part of the dielectric film IL2 also contributes as an electron conduction path.

As shown in FIG. 16, when the thickness of the Si—Cr—C resistor element RS101 is large, most of the current flows through the interior of the Si—Cr—C resistor element RS101, so the contribution of the conduction path indicated by the arrow YG2 or the arrow YG3 is small. Therefore, the resistance value of the conduction path passing through the dielectric film IL2 or the dielectric film IL3 hardly contributes to the total resistance value of the Si—Cr—C resistor element RS101.

However, compared to the case where the thickness of the Si—Cr—C resistor element RS101 is large as shown in FIG. 16, when the thickness of the Si—Cr—C resistor element RS101 is small as shown in FIG. 17, the current flowing through the interior of the Si—Cr—C resistor element RS101 decreases, so the contribution of the conduction path indicated by the arrow YG2 or the arrow YG3 becomes larger. Therefore, the proportion of the resistance value of the conduction path passing through the dielectric film IL2 or the dielectric film IL3 to the total resistance value of the Si—Cr—C resistor element RS101 increases.

In the conduction path (YG2) passing through the dielectric film IL3 and the conduction path (YG3) passing through the dielectric film IL2, the resistance value changes greatly due to temperature changes, the temperature coefficient of resistance becomes negative, and the absolute value of the temperature coefficient of resistance increases. Therefore, as the thickness of the Si—Cr—C resistor element RS101 decreases, the influence of the conduction path passing through the dielectric film IL2 or the dielectric film IL3 becomes larger, and as a result, the absolute value of the temperature coefficient of resistance increases. Even when the thickness of the Si—Cr—C resistor element is reduced, it is desirable to suppress the absolute value of the temperature coefficient of resistance.

### Resistor Element

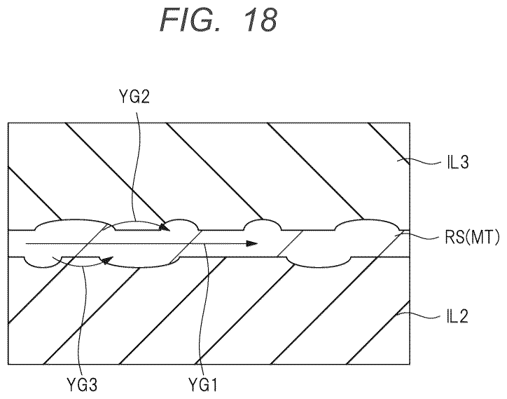

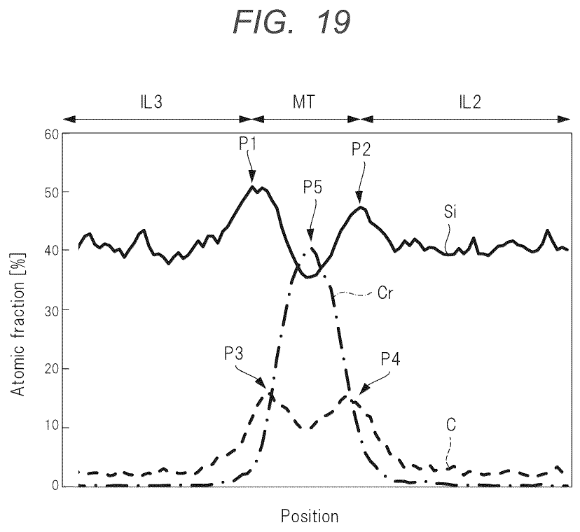

FIG. 18 is a partial enlarged cross-sectional view of a part of the above-mentioned FIG. 1. FIG. 19 is a graph showing the concentration distribution of silicon (Si), chromium (Cr), and carbon (C) in the laminated structure shown in FIG. 18. The horizontal axis of the graph in FIG. 19 corresponds to the depth position. The vertical axis of the graph in FIG. 19 corresponds to the atomic fraction (concentration) of silicon (Si), chromium (Cr), or carbon (C). In the graph of FIG. 19, the concentration distribution of silicon (Si) is shown by a solid line, the concentration distribution of carbon (C) is shown by a dotted line, and the concentration distribution of chromium (Cr) is shown by a dashed line. The graph in FIG. 19 is based on the analysis results by EDX (Energy Dispersive X-ray Spectroscopy).

In the present embodiment, during the manufacturing step of the semiconductor device, a crystallization annealing treatment is applied to the material layer MT as described above. The graph in FIG. 19 is a graph of the results of analyzing the concentration distribution of each element when a crystallization annealing treatment is applied to the material layer MT as in the present embodiment.

As can be seen from the graph in FIG. 19, in the present embodiment, the composition ratio of silicon (Si), chromium (Cr), and carbon (C) in the resistor element RS is not uniformly distributed in the thickness direction, but has the following distribution. The thickness direction refers to the direction from the lower surface to the upper surface of the resistor element RS, or the direction from the upper surface to the lower surface of the resistor element RS. The upper surface of the resistor element RS is the interface between the resistor element RS and the dielectric film IL3. The lower surface of the resistor element RS is the interface between the resistor element RS and the dielectric film IL2. FIG. 19 shows the concentration distribution in the thickness direction.

As shown in the graph in FIG. 19, in the resistor element RS, the peak P1 of the silicon (Si) concentration is formed at a position in the vicinity of the upper surface of the resistor element RS, and the peak P2 of the silicon concentration is formed at a position in the vicinity of the lower surface of the resistor element RS.

The silicon (Si) concentration in the resistor element RS (material layer MT) increases from the center part of the resistor element RS towards the upper surface of the resistor element RS. Also, the silicon (Si) concentration in the resistor element RS (material layer MT) increases from the center part of the resistor element RS towards the lower surface of the resistor element RS. That is, the silicon (Si) concentration in the resistor element RS is lowest at the center part of the resistor element RS, increases towards the upper surface from the center part, and also increases towards the lower surface from the center part. Therefore, in the resistor element RS, the silicon (Si) concentration in the vicinity of the upper surface of the resistor element RS and in the vicinity of the lower surface of the resistor element RS is greater than the silicon (Si) concentration at the center part of the resistor element RS. The center part of the resistor element RS refers to the center part in the thickness direction of the resistor element RS.

As shown in the graph in FIG. 19, in the resistor element RS, the peak P3 of the carbon (C) concentration is formed at a position in the vicinity of the upper surface of the resistor element RS, and the peak P4 of the carbon concentration is formed at a position in the vicinity of the lower surface of the resistor element RS.

The carbon (C) concentration in the resistor element RS (material layer MT) increases from the center part of the resistor element RS towards the upper surface of the resistor element RS. Also, the carbon (C) concentration in the resistor element RS (material layer MT) increases from the center part of the resistor element RS towards the lower surface of the resistor element RS. That is, the carbon (C) concentration in the resistor element RS is lowest at the center part of the resistor element RS, increases towards the upper surface from the center part, and also increases towards the lower surface from the center part. Therefore, in the resistor element RS, the carbon (C) concentration in the vicinity of the upper surface of the resistor element RS and in the vicinity of the lower surface of the resistor element RS is greater than the carbon (C) concentration at the center part of the resistor element RS.

As shown in the graph in FIG. 19, in the resistor element RS, the peak P5 of the chromium (Cr) concentration is formed at the center part of the resistor element RS.

The chromium (Cr) concentration in the resistor element RS (material layer MT) decreases from the center part of the resistor element RS towards the upper surface of the resistor element RS. Also, the chromium (Cr) concentration in the resistor element RS (material layer MT) decreases from the center part of the resistor element RS towards the lower surface of the resistor element RS. That is, the concentration of chromium (Cr) in the resistor element RS is highest in the center part of the resistor element RS, decreases towards the upper surface from the center part, and also decreases towards the lower surface from the center part. Therefore, in the resistor element t RS, the concentration of chromium (Cr) in the vicinity of the upper surface of the resistor element RS and in the vicinity of the lower surface of the resistor element RS is smaller than the concentration of silicon (Si) in the center part of the resistor element RS.

The concentrations of silicon (Si), chromium (Cr), and carbon (C) are all based on the number of atoms, and are expressed in atomic percent.

Reflecting the concentration distribution of silicon (Si) and chromium (Cr) in the resistor element RS, the Si/Cr ratio in the resistor element RS shows the following distribution.

The Si/Cr ratio in the resistor element RS (material layer MT) increases from the center part of the resistor element RS towards the upper surface of the resistor element RS. Also, the Si/Cr ratio in the resistor element RS (material layer MT) increases from the center part of the resistor element RS towards the lower surface of the resistor element RS. That is, the Si/Cr ratio in the resistor element RS is lowest in the center part of the resistor element RS, increases towards the upper surface from the center part, and also increases towards the lower surface from the center part. Therefore, in the resistor element RS, the Si/Cr ratio in the vicinity of the upper surface of the resistor element RS and in the vicinity of the lower surface of the resistor element RS is greater than the Si/Cr ratio in the center part of the resistor element RS.

As can be understood from the graph of FIG. 14, in the Si—Cr—C resistor element, the larger the Si/Cr ratio, the greater the resistivity. Therefore, reflecting the distribution of the Si/Cr ratio in the resistor element RS, the resistivity in the resistor element RS shows the following distribution.

The resistivity in the resistor element RS (material layer MT) increases from the center part of the resistor element RS towards the upper surface of the resistor element RS. Also, the resistivity in the resistor element RS (material layer MT) increases from the center part of the resistor element RS towards the lower surface of the resistor element RS. That is, the resistivity in the resistor element RS is lowest at the center part of the resistor element RS, increases towards the upper surface from the center part, and also increases towards the lower surface from the center part. Therefore, in the resistor element RS, the resistivity in the vicinity of the upper surface of the resistor element RS and in the vicinity of the lower surface of the resistor element RS is greater than the resistivity at the center part of the resistor element RS.

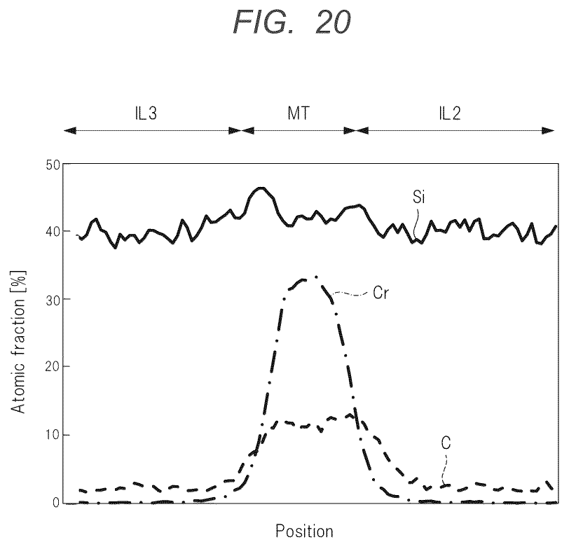

FIG. 20 is a graph showing the results of analyzing the concentration distribution of silicon (Si), chromium (Cr), and carbon (C) when the material layer MT is not subjected to crystallization annealing treatment as the examined example. The horizontal and vertical axes of FIG. 20 are the same as those of FIG. 19. Like FIG. 19, the graph of FIG. 20 is based on the analysis results by EDX.

Unlike the present embodiment, when the material layer MT is not subjected to crystallization annealing treatment, as can be seen from the graph of FIG. 20, the concentration distribution of silicon (Si) in the material layer MT is almost uniform in the thickness direction. Also, the concentration distribution of carbon (C) in the material layer MT is almost uniform in the thickness direction. Also, as can be seen by comparing the graph of FIG. 19 and the graph of FIG. 20, the distribution curve of chromium concentration in the graph of FIG. 20 is broader than the distribution curve of chromium concentration in the graph of FIG. 19. Therefore, compared to the case of the graph of FIG. 19, in the case of the graph of FIG. 20, the concentration distribution of chromium (Cr) in the material layer MT is considered to be nearly uniform.

Therefore, compared to when the material layer MT is subjected to crystallization annealing treatment, when the material layer MT is not subjected to crystallization annealing treatment, the composition ratio of chromium (Cr) and carbon (C) is considered to be nearly uniform in the thickness direction.

On the other hand, in the present embodiment, during the manufacturing steps of the semiconductor device, crystallization annealing treatment is applied to the material layer MT. This crystallization annealing treatment is performed while the material layer MT is sandwiched between the dielectric film IL2 and the dielectric film IL3. That is, the lower surface of the material layer MT is covered by the dielectric film IL2, and the upper surface of the material layer MT is covered by the dielectric film IL3, and the crystallization annealing treatment is performed on the material layer MT. Therefore, during the crystallization annealing treatment, silicon (Si) and carbon (C) in the material layer MT diffuse towards the interface between the material layer MT and the dielectric film IL3, segregate in the vicinity of the upper surface of the material layer MT in the resistor element RS, and also diffuse towards the interface between the material layer MT and the dielectric film IL2, segregate in the vicinity of the lower surface of the material layer MT in the resistor element RS. This is considered to have formed the concentration distribution shown in the graph of FIG. 19.

Unlike the present embodiment, when the crystallization annealing treatment is performed in a state where the upper surface of the material layer MT is not covered by a dielectric film, the concentration distribution shown in the graph of FIG. 19 is not formed. This is because, during the crystallization annealing treatment, silicon (Si) and carbon (C) in the material layer MT diffuse towards the interface between the material layer

MT and the dielectric film IL2, but hardly diffuse towards the upper surface of the material layer MT, and silicon (Si) and carbon (C) do not segregate in the vicinity of the upper surface of the material layer MT in the resistor element RS.

In the present embodiment, the upper surface of the material layer MT is covered by the dielectric film IL3, and a crystallization annealing treatment is performed. During the crystallization annealing treatment, silicon (Si) and carbon (C) in the material layer MT can diffuse towards the interface between the material layer MT and the dielectric film IL3, and also towards the interface between the material layer MT and the dielectric film IL2. As a result, silicon (Si) and carbon (C) segregate in the vicinity of the upper surface and in the vicinity of the lower surface of the material layer MT, forming a concentration distribution as shown in the graph of FIG. 19.

In the present embodiment, as described above, the concentration of silicon (Si) in the resistor element RS (material layer MT) increases from the center part of the resistor element RS towards the upper surface of the resistor element RS. Also, the concentration of silicon (Si) in the resistor element RS (material layer MT) increases from the center part of the resistor element RS towards the lower surface of the resistor element RS. Reflecting this, the Si/Cr ratio is low in the center part of the resistor element RS, and the Si/Cr ratio is high in the vicinity of the upper surface and in the vicinity of the lower surface of the resistor element RS compared to the center part of the resistor element RS. As a result, the absolute value of the temperature coefficient of resistance of the resistor element RS can be suppressed for the following two reasons.

The first reason is explained. In the resistor element RS, the Si/Cr ratio increases in the vicinity of the upper surface and in the vicinity of the lower surface of the resistor element RS, resulting in a higher resistivity in the vicinity of the upper surface and in the vicinity of the lower surface of the resistor element RS, making it difficult for current to flow. As a result, the current flowing through the conduction path (YG1) passing through the interior of the resistor element RS increases, and the current flowing through the conduction path (YG2) passing through the dielectric film IL3 and the conduction path (YG3) passing through the dielectric film IL2 decreases. Therefore, the proportion of the resistance value of the conduction path (YG2, YG3) passing through the dielectric films IL2 or IL3 to the total resistance value of the resistor element RS can be reduced. As described above, the temperature coefficient of resistance becomes negative and the absolute value of the temperature coefficient of resistance increases in the conduction path (YG2) passing through the dielectric film IL3 and the conduction path (YG3) passing through the dielectric film IL2. In the present embodiment, since the proportion of the resistance value of the conduction path (YG2, YG3) passing through the dielectric film IL2 or IL3 to the total resistance value of the resistor element RS can be reduced, the absolute value of the temperature coefficient of resistance of the resistor element RS can be suppressed.

The second reason is explained. In the center part of the resistor element RS, the resistivity decreases due to the low Si/Cr ratio, so the current passing through the center part of the resistor element RS increases. As can be seen from the graph in FIG. 14, when the Si/Cr ratio increases, the absolute value of the temperature coefficient of resistance of the Si—Cr—C resistor element tends to increase. In the present embodiment, by increasing the current flowing through the center part of the resistor element RS and lowering the Si/Cr ratio in the center part, the absolute value of the temperature coefficient of resistance of the resistor element RS can be suppressed.

As explained with reference to FIGS. 16 and 17, when the thickness of the Si—Cr—C resistor element RS101 becomes small, the influence of the conduction path (YG2, YG3) passing through the dielectric films IL2 or IL3 becomes large, and as a result, the absolute value of the temperature coefficient of resistance increases.

In the present embodiment, even when the thickness of the resistor element RS is reduced, the absolute value of the temperature coefficient of resistance of the resistor element RS can be suppressed due to the first and second reasons mentioned above. Therefore, in the present embodiment, the thickness of the resistor element RS can be reduced while suppressing the absolute value of the temperature coefficient of resistance of the resistor element RS. By reducing the thickness of the resistor element RS, the planar dimensions of the resistor element RS can be reduced while increasing the resistance value of the resistor element RS, enabling the miniaturization of the semiconductor device including the resistor element RS. By suppressing the absolute value of the temperature coefficient of resistance of the resistor element RS, it is possible to suppress changes in the resistance value of the resistor element RS due to temperature changes, thereby improving the performance of the semiconductor device including the resistor element RS.

Therefore, the present embodiment is highly effective when applied to cases where the thickness of the resistor element RS is reduced. Specifically, the present embodiment is highly effective when applied to cases where the thickness of the resistor element RS is 10 nm or less.

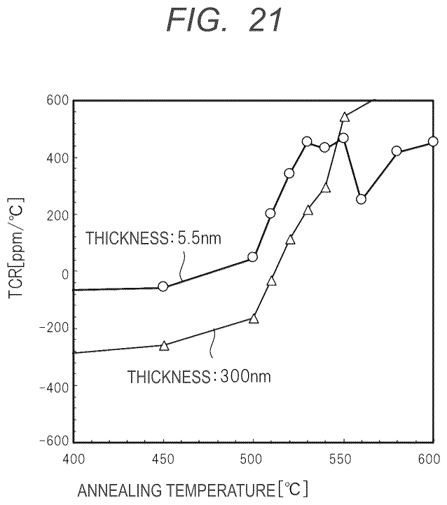

FIG. 21 is a graph showing the correlation between the crystallization annealing temperature and the temperature coefficient of resistance (TCR) of the resistor element RS. The horizontal axis of the graph in FIG. 21 corresponds to the crystallization annealing temperature of the resistor element RS (material layer MT). The vertical axis of the graph in FIG. 21 corresponds to the temperature coefficient of resistance (TCR) of the resistor element RS. The graph in FIG. 21 shows the case where the thickness of the resistor element RS is 300 nm and the case where the thickness of the resistor element RS is 5.5 nm. From the graph in FIG. 21, it can be seen that the absolute value of the temperature coefficient of resistance (TCR) can be suppressed when the thickness of the resistor element RS is 5.5 nm compared to when it is 300 nm. Also, from the graph in FIG. 21, it can be seen that if the crystallization annealing temperature is 500 degrees Celsius or less when the thickness of the resistor element RS is 5.5 nm, the absolute value of the temperature coefficient of resistance (TCR) of the resistor element RS can be sufficiently suppressed.

Therefore, in the present embodiment, it is preferable to set the thickness of the resistor element RS to 10 nm or less and the crystallization annealing temperature of the resistor element RS (material layer MT) to 500 degrees Celsius or less. It is even more preferable to set the crystallization annealing temperature to 300 degrees Celsius or more and 500 degrees Celsius or less. This can further suppress the absolute value of the temperature coefficient of resistance of the resistor element RS.

Also, by setting the crystallization annealing temperature to 500 degrees Celsius or less, it is possible to suppress or prevent the crystallization annealing from affecting the plurality of wirings Ml or semiconductor elements formed on the semiconductor substrate SB. Therefore, the reliability of the semiconductor device can be improved.

It is also preferable that the ratio of silicon (Si) to chromium (Cr) in the resistor element RS (Si/Cr ratio) is greater than 2 and the carbon (C) content in the resistor element RS is 15 atomic percent or more and 30 atomic percent or less. By satisfying such a content, a good balance between the resistivity and the absolute value of the temperature coefficient of resistance of the resistor element RS can be obtained when the crystallization annealing treatment is performed.

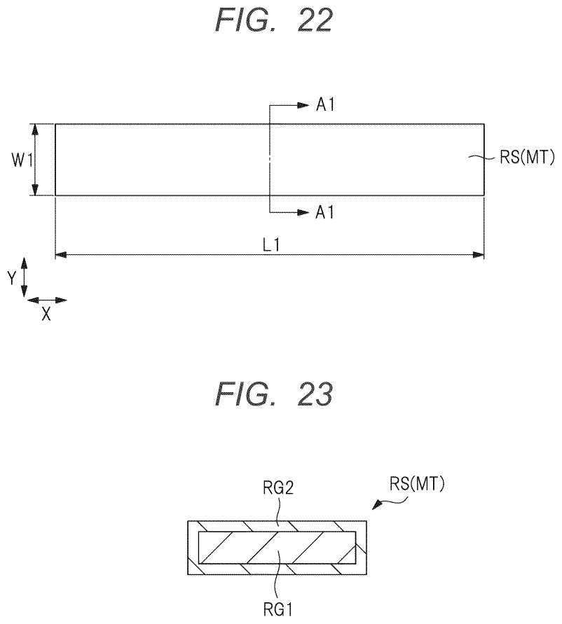

FIG. 22 is a plan view of the resistor element RS. FIG. 23 is a cross-sectional view of the resistor element RS. The cross-sectional view along the line A1-A1 in FIG. 22 corresponds to FIG. 23. The X direction and the Y direction shown in FIG. 22 are orthogonal to each other. Also, the X direction and the Y direction shown in FIG. 22 are substantially parallel to the main surface of the semiconductor substrate SB. The X direction is the long side direction of the resistor element RS, and the Y direction is the short side direction of the resistor element RS.

As shown in FIG. 22, the resistor element RS has the length L1 and the width W1. The length L1 is the dimension of the resistor element RS in the X direction. The width W1 is the dimension of the resistor element RS in the Y direction. In the resistor element RS, the current flows in the X direction.

As schematically shown in FIG. 23, the resistor element RS has a low resistance region RG1 and a high resistance region RG2. The resistivity of the high resistance region RG2 is higher than the resistivity of the low resistance region RG1.

As shown in FIG. 23, in a cross-sectional view orthogonal to the X direction, the low resistance region RG1 is surrounded by the high resistance region RG2. In the resistor element RS, the high resistance region RG2 is formed of a region adjacent to the upper surface of the resistor element RS, a region adjacent to the lower surface of the resistor element RS, and a region adjacent to the side surface of the resistor element RS. In other words, in the resistor element RS, the high resistance region RG2 is configured by a region in the vicinity of the upper surface of the resistor element RS, a region in the vicinity of the lower surface of the resistor element RS, and a region in the vicinity of the side surface of the resistor element RS. The center part of the resistor element RS is included in the low resistance region RG1.

Compared to the low resistance region RG1, in the high resistance region RG2, the concentration of silicon (Si) is high, the concentration of carbon (C) is high, and the concentration of chromium (Cr) is low. That is, compared to the center part of the resistor element RS, in the region in the vicinity of the upper surface of the resistor element RS, in the region in the vicinity of the lower surface of the resistor element RS, and in the region in the vicinity of the side surface of the resistor element RS in the resistor element RS, the concentration of silicon (Si) is high, the concentration of carbon (C) is high, and the concentration of chromium (Cr) is low. This is because the resistor element RS has a concentration distribution as shown in FIG. 19. Reflecting this, the Si/Cr ratio in the high resistance region RG2 is greater than the Si/Cr ratio in the low resistance region RG1, and as a result, the resistivity of the high resistance region RG2 is greater than the resistivity of the low resistance region RG1.

In the present embodiment, after patterning the material layer MTa to form the material layer MT, the dielectric film IL3 is formed to cover the material layer MT, and then, a crystallization annealing treatment is performed. Therefore, the lower surface of the material layer MT is covered by the dielectric film IL2, and the upper surface and side surface of the material layer MT are covered by the dielectric film IL3, and the crystallization annealing treatment is performed on the material layer MT. Therefore, during the crystallization annealing treatment, silicon (Si) and carbon (C) in the material layer MT diffuse towards the upper surface of the material layer MT, forming the high resistance region RG2 in the region adjacent to the upper surface of the resistor element RS. Also, during the crystallization annealing treatment, silicon (Si) and carbon (C) in the material layer MT diffuse towards the lower surface of the material layer MT, forming the high resistance region RG2 in the region adjacent to the lower surface of the resistor element RS. During the crystallization annealing treatment, silicon (Si) and carbon (C) in the material layer MT diffuse towards the side surface of the material layer MT, forming the high resistance region RG2 in the region adjacent to the side surface of the resistor element RS. As a result, a cross-sectional structure as shown in FIG. 23 is formed.

By forming the low resistance region RG1 and the high resistance region RG2 in the resistor element RS, the absolute value of the temperature coefficient of resistance of the resistor element RS can be suppressed due to the first and second reasons.

Not only the high resistance region RG2 adjacent to the upper surface of the resistor element RS and the high resistance region RG2 adjacent to the lower surface of the resistor element RS, but also the high resistance region RG2 adjacent to the side surface of the resistor element RS contribute to the effect of suppressing the absolute value of the temperature coefficient of resistance of the resistor element RS. The effect of forming the low resistance region RG1 and the high resistance region RG2 in the resistor element RS increases as the width W1 of the resistor element RS decreases. This is because even if the width W1 of the resistor element RS is reduced, the size of the high resistance region RG2 adjacent to the side surface of the resistor element RS does not change.

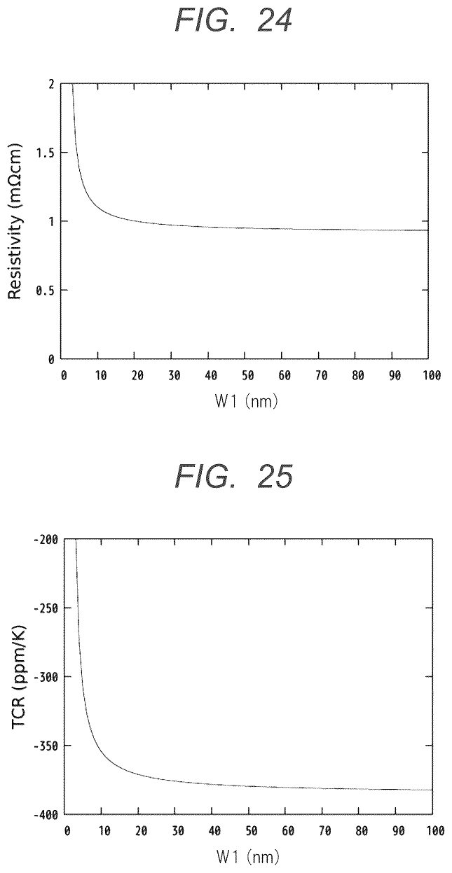

FIG. 24 is a graph showing the correlation between the width W1 of the resistor element RS and the resistance value of the resistor element RS. FIG. 25 is a graph showing the correlation between the width W1 of the resistor element RS and the temperature coefficient of resistance of the resistor element RS. The horizontal axis of each graph in FIGS. 24 and 25 corresponds to the width W1 of the resistor element RS. The vertical axis of the graph in FIG. 24 corresponds to the resistance value of the resistor element RS. The vertical axis of the graph in FIG. 25 corresponds to the temperature coefficient of resistance of the resistor element RS. Each graph in FIGS. 24 and 25 is based on analysis by simulation.

From the graph in FIG. 24, it can be seen that the smaller the width W1 of the resistor element RS, the larger the resistance value of the resistor element RS. From the graph in FIG. 25, it can be seen that the smaller the width W1 of the resistor element RS, the higher the temperature coefficient of resistance of the resistor element RS, and the smaller the absolute value of the temperature coefficient of resistance of the resistor element RS.

Therefore, the smaller the width W1 of the resistor element

RS, the greater the effect of the present embodiment. Specifically, when the width W1 of the resistor element RS is 40 nm or less, the effect of the present embodiment is significant, and when the width W1 of the resistor element RS is 10 nm or less, the effect of the present embodiment is even greater. When the width W1 of the resistor element RS is greater than 10 nm and 40 nm or less, the change in the resistance value of the resistor element RS and the change in the temperature coefficient of resistance of the resistor element RS are small when the width W1 of the resistor element RS is changed, making the design of the resistor element RS easy.

When the width W1 of the resistor element RS is 10 nm or less, the increase in the resistance value of the resistor element RS and the reduction in the absolute value of the temperature coefficient of resistance of the resistor element RS can be increased.

### MODIFIED EXAMPLE

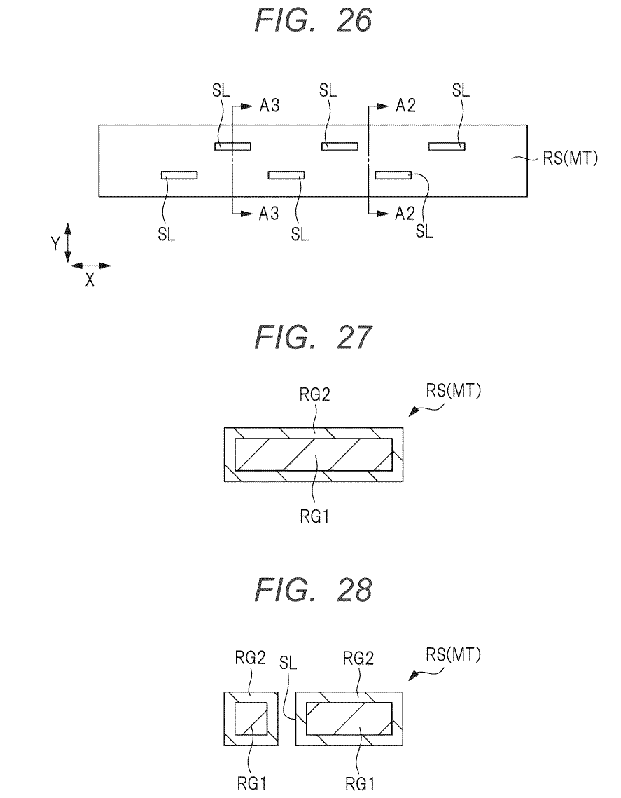

FIG. 26 is a plan view of the resistor element RS of the modified example. FIG. 27 is a cross-sectional view of the resistor element RS of the modified example along line A2-A2 in FIG. 26. FIG. 28 is a cross-sectional view of the resistor element RS of the modified example along line A3-A3 in FIG. 26.

The resistor element RS of the modified example shown in FIG. 26 differs from the resistor element RS shown in FIG. 22 in that the resistor element RS has a slit SL.

The number of slits SL formed in the resistor element RS is one or more, but it is preferable to have the plurality of. In the case of FIG. 26, each slit SL extends in the X direction. As can be seen from FIG. 28, the slit SL of the resistor element RS is formed to penetrate from the upper surface to the lower surface of the resistor element RS. In other words, the slit SL of the resistor element RS is formed to expose the dielectric film IL1. A through hole that penetrates through the resistor element RS can also be applied as the slit SL.

As shown in FIGS. 27 and 28, in a cross-sectional view orthogonal to the X direction, the low resistance region RG1 is surrounded by the high resistance region RG2. In the resistor element RS, the high resistance region RG2 is formed of a region adjacent to the upper surface of the resistor element RS, a region adjacent to the lower surface of the resistor element RS, a region adjacent to the side surface of the resistor element RS, and a region adjacent to the inner wall of the slit SL. In other words, in the resistor element RS, the high resistance region RG2 is formed of a region in the vicinity of the upper surface of the resistor element RS, a region in the vicinity of the lower surface of the resistor element RS, a region in the vicinity of the side surface of the resistor element RS, and a region in the vicinity of the inner wall of the slit SL. Compared to the low resistance region RG1, the silicon (Si) concentration is high, the carbon (C) concentration is high, and the chromium (Cr) concentration is low in the high resistance region RG2.

The silicon concentration of the part of the resistor element RS that contacts the slit SL is higher than the silicon concentration of the part of the resistor element RS that is away from the slit SL, the upper surface of the resistor element RS, the side surface of the resistor element RS, and the lower surface of the resistor element RS. Also, the carbon concentration of the part of the resistor element RS that contacts the slit SL is higher than the carbon concentration of the part of the resistor element RS that is away from the slit SL, the upper surface of the resistor element RS, the side surface of the resistor element RS, and the lower surface of the resistor element RS. Also, the chromium concentration of the part of the resistor element RS that contacts the slit SL is lower than the chromium concentration of the part of the resistor element RS that is away from the slit SL, the upper surface of the resistor element RS, the side surface of the resistor element RS, and the lower surface of the resistor element RS.

Not only the high resistance region RG2 adjacent to the upper surface of the resistor element RS, the high resistance region RG2 adjacent to the lower surface of the resistor element RS, and the high resistance region RG2 adjacent to the side surface of the resistor element RS, but also the high resistance region RG2 adjacent to the inner wall of the slit SL contribute to the effect of suppressing the absolute value of the temperature coefficient of resistance of the resistor element RS. Therefore, the resistor element RS of the modified example shown in FIGS. 26, 27, and 28 can further increase the effect of suppressing the absolute value of the temperature coefficient of resistance of the resistor element RS compared to the resistor element RS shown in FIGS. 22 and 23.

### SECOND EMBODIMENT

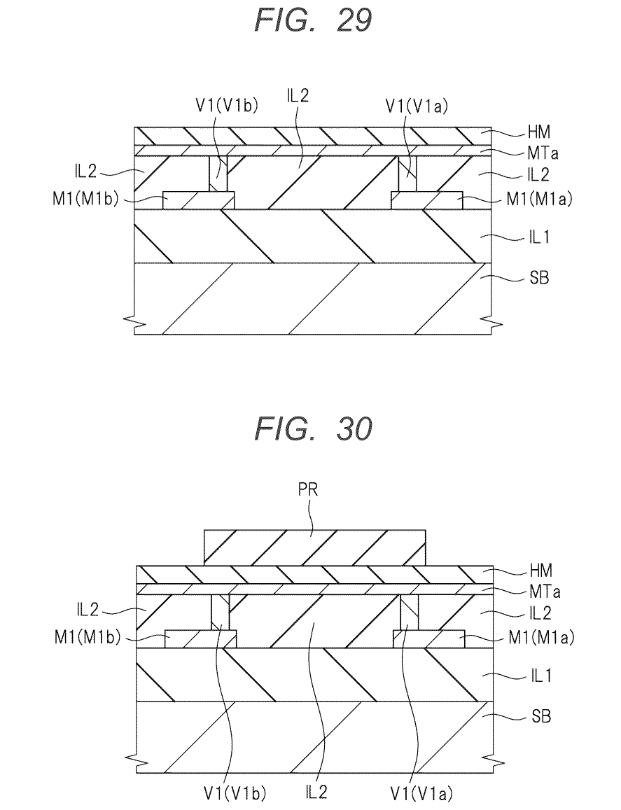

The manufacturing steps of the semiconductor device of the present second embodiment will be described with reference to the drawings. FIGS. 29 to 33 are cross-sectional views of the main portions during the manufacturing steps of the semiconductor device of the present second embodiment.

In the second embodiment as well, similar to the first embodiment, the steps from FIG. 2 to FIG. 8 are performed. After forming the material layer MTa in the same manner as in the first embodiment, in the second embodiment, as shown in FIG. 29, a dielectric film HM is formed on the material layer MTa.

The dielectric film HM is a dielectric film that functions as a hard mask. The dielectric film HM can be formed of materials such as silicon oxide films and formed using methods such as CVD method.

Next, as shown in FIG. 30, a photoresist pattern PR is formed on the dielectric film HM using photolithography techniques.

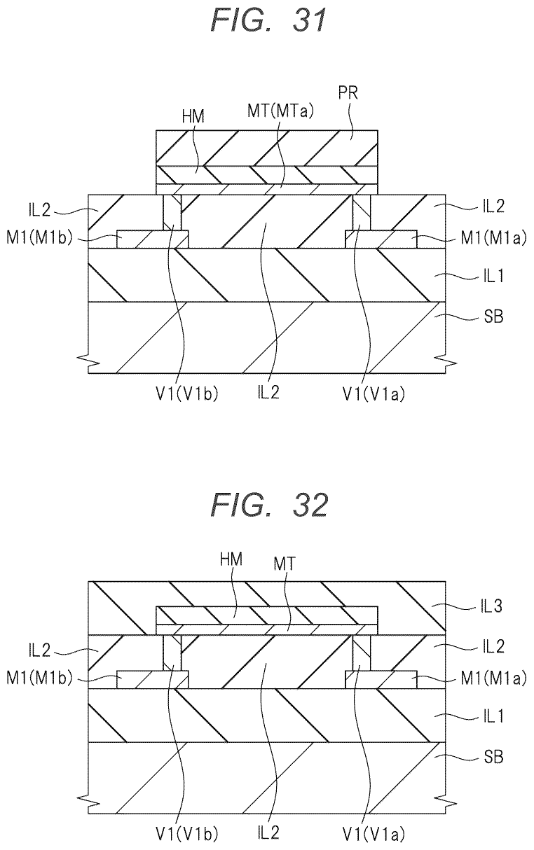

Next, as shown in FIG. 31, the dielectric film HM is etched using the photoresist pattern PR as an etching mask. This results in the patterning of the dielectric film HM.

Next, as shown in FIG. 31, the material layer MTa is etched using the photoresist pattern PR and the dielectric film HM as etching masks. This results in the patterning of the material layer MTa to form the material layer MT. The material layer MT is formed of the patterned material layer MTa. Subsequently, the photoresist pattern PR is removed by ashing or the like. The dielectric film HM having the same planar shape as the material layer MT is disposed on the upper surface of the material layer MT. The upper surface of the material layer MT contacts the dielectric film HM.

Alternatively, after etching the dielectric film HM using the photoresist pattern PR as an etching mask, the photoresist pattern PR can be removed, and then the material layer MTa can be etched using the dielectric film HM as an etching mask.

Next, as shown in FIG. 32, the dielectric film IL3 is formed on the dielectric film IL2 so as to cover the laminate film formed of the material layer MT and the dielectric film HM on the material layer MT. The dielectric film IL3 is formed so as to contact the side surface of the material layer MT, the upper surface of the dielectric film HM, and the side surface of the dielectric film HM. After forming the dielectric film IL3, the upper surface of the dielectric film IL3 can be planarized using methods such as CMP method.

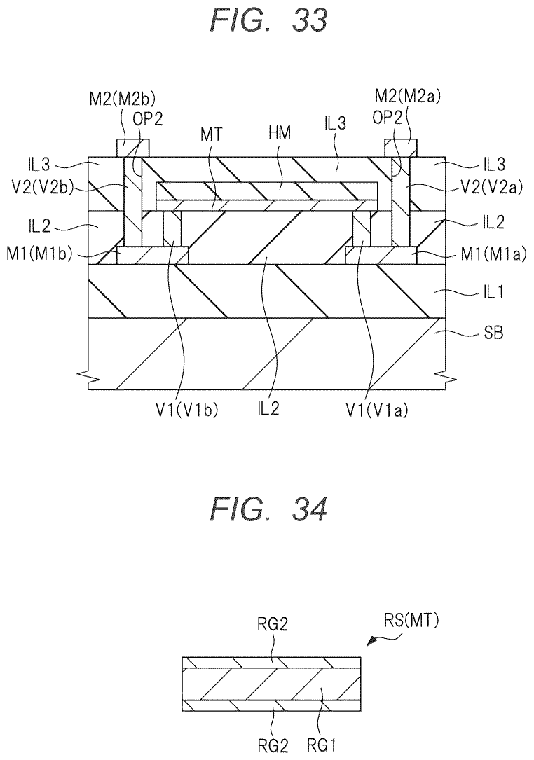

Next, in the second embodiment as well, similar to the first embodiment, as shown in FIG. 33, the plurality of openings OP2 penetrating through the dielectric films IL3 and IL2 are formed. Next, similar to the first embodiment, as shown in FIG. 33, the plurality of plugs V2 are formed. Next, similar to the first embodiment, as shown in FIG. 33, the plurality of wirings M2 are formed.

The illustration and explanation of the step of forming the upper layer dielectric film and wiring are omitted. In the first embodiment, the crystallization annealing treatment for the material layer MT is performed after the formation of the dielectric film IL3. As a result, a concentration distribution as shown in the graph of FIG. 19 is is formed because the crystallization annealing treatment performed with the dielectric film IL3 disposed on the material layer MT.

In the second embodiment, the crystallization annealing treatment is performed after the formation of the dielectric film HM. As a result, a concentration distribution as shown in the graph of FIG. 19 is formed because the crystallization annealing treatment is performed with the dielectric film HM disposed on the material layer MTa or the material layer MT.

In the second embodiment, the crystallization annealing treatment can be performed at any of the timings explained below.

In the second embodiment, the crystallization annealing treatment can be performed after forming the dielectric film IL3.

This crystallization annealing treatment causes a part or all of the amorphous material layer MT to crystallize. A concentration distribution as shown in the graph of FIG. 19 is formed because the crystallization annealing treatment is performed with the upper surface of the material layer MT covered by the dielectric film HM and the side surface of the material layer MT covered by the dielectric film IL3. Also, a cross-sectional structure as shown in FIG. 23 can be obtained.

Alternatively, in the second embodiment, the crystallization annealing treatment can be performed after patterning the material layer MTa to form the material layer MT, and before forming the dielectric film IL3. By this crystallization annealing treatment, some or all of the amorphous material layer MT is crystallized. Since the crystallization annealing treatment is performed with the upper surface of the material layer MT covered by the dielectric film HM, a concentration distribution as shown in the graph of FIG. 19 is formed. Also, a cross-sectional structure as shown in FIG. 23 can be obtained.

Alternatively, in the second embodiment, the crystallization annealing treatment can be performed after forming the dielectric film HM, and before forming the photoresist pattern PR. By this crystallization annealing treatment, some or all of the amorphous material layer MTa is crystallized. Since the crystallization annealing treatment is performed with the upper surface of the material layer MTa covered by the dielectric film HM, a concentration distribution as shown in the graph of FIG. 19 is formed. Also, a cross-sectional structure as shown in FIG. 34 can be obtained.

FIG. 34 is a cross-sectional view of the resistor element RS, showing a cross-section corresponding to FIG. 23. If the crystallization annealing treatment performed before is patterning the material layer MTa, as shown in FIG. 34, the high resistance region RG2 is not formed in the region adjacent to the side surface of the resistor element RS (material layer MT). When the high resistance region RG2 is formed in the region adjacent to the side surface of the resistor element RS, the effect of suppressing the absolute value of the temperature coefficient of resistance of the resistor element RS is greater than when the high resistance region RG2 is not formed in the region adjacent to the side surface of the resistor element RS. That is, compared to the cross-sectional structure of FIG. 34, when the cross-sectional structure of FIG. 23 is formed, the effect of suppressing the absolute value of the temperature coefficient of resistance of the resistor element RS is greater.

### THIRD EMBODIMENT

According to the study by the present inventors, it was found that carbon (C) adheres to the upper surface of the dielectric film IL2 before forming the material layer MTa, and this carbon changes the temperature coefficient of resistance of the resistor element RS. The carbon adhering to the upper surface of the dielectric film IL2 is believed to originate from organic matter present inside various manufacturing apparatuses or transport apparatuses. When the material layer MTa is formed on the dielectric film IL2 with carbon (C) adhered to the upper surface of the dielectric film IL2, the carbon (C) adhered to the upper surface of the dielectric film IL2 diffuses into the material layer MTa or the material layer MT during crystallization annealing. Since the 4 carbon (C) adhering to the upper surface of the dielectric film IL2 and the amount of carbon (C) diffusing into the material layer MTa or the material layer MT during crystallization annealing vary, the carbon (C) content of the resistor element RS varies. As a result, the temperature coefficient of resistance of the resistor element RS is not stable and varies.

Therefore, in the present embodiment, a cleaning treatment is performed on the upper surface of the dielectric film IL2 after forming the plurality of plugs VI and before forming the material layer MTa. By this cleaning treatment, it is possible to remove the carbon adhered to the upper surface of the dielectric film IL2. As a result, it is possible to suppress or prevent the variation in the carbon (C) content of the resistor element RS. This can suppress the variation in the temperature coefficient of resistance of the resistor element RS. Therefore, the reliability of the semiconductor device including the resistor element RS can be improved.

A plasma cleaning treatment is preferable as the cleaning treatment. For example, after performing a plasma treatment using argon (Ar) plasma on the upper surface of the dielectric film IL2, the material layer MTa is formed on the dielectric film IL2.

It is preferable to perform the plasma cleaning treatment and the film formation step of the material layer MTa continuously without exposing the semiconductor substrate SB to the atmosphere. That is, the semiconductor substrate SB is loaded into the chamber of the plasma apparatus, and after performing the plasma cleaning treatment on the upper surface of the dielectric film IL2, the semiconductor substrate SB is unloaded from the chamber of the plasma apparatus. Then, the semiconductor substrate SB, which has been unloaded from the chamber of the plasma apparatus, is loaded into the chamber of the film formation apparatus without being exposed to the atmosphere, and the material layer MTa is formed on the dielectric film IL2. This can prevent carbon (C) from re-adhering to the upper surface of the dielectric film IL2 after the plasma cleaning treatment and before the film formation step of the material layer MTa.

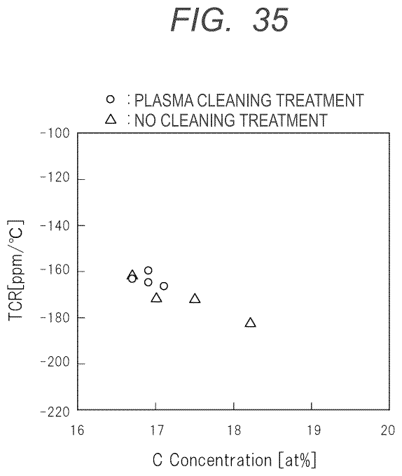

FIG. 35 is a graph showing the carbon (C) content and the temperature coefficient of resistance of the resistor element RS. The horizontal axis of the graph in FIG. 35 corresponds to the carbon (C) content of the resistor element RS, and the vertical axis of the graph in FIG. 35 corresponds to the temperature coefficient of resistance of the resistor element RS. Also, the graph in FIG. 35 plots the measurement results of the carbon (C) content and the temperature coefficient of resistance of the resistor element RS when the plasma cleaning treatment is performed on the upper surface of the dielectric film IL2, and the measurement results of the carbon (C) content and the temperature coefficient of resistance of the resistor element RS when no cleaning treatment is performed on the upper surface of the dielectric film IL2. The number of samples when the plasma cleaning treatment is performed on the upper surface of the dielectric film IL2 is four. Also, the number of samples when no cleaning treatment is performed on the upper surface of the dielectric film IL2 is four.

As can be seen from the graph in FIG. 35, when no cleaning treatment is performed on the upper surface of the dielectric film IL2, the carbon (C) content and the temperature coefficient of resistance of the resistor element RS fluctuate. It is believed that the carbon (C) adhering to the upper surface of the dielectric film IL2 diffuses into the material layer MTa or the material layer MT during the crystallization annealing, causing the carbon (C) content of the resistor element RS to fluctuate, and as a result, the temperature coefficient of resistance of the resistor element RS fluctuates.

On the other hand, when the plasma cleaning treatment is performed on the upper surface of the dielectric film IL2, as can be seen from the graph in FIG. 35, the fluctuation of the carbon (C) content and the temperature coefficient of resistance of the resistor element RS is suppressed.

As a cleaning treatment for the upper surface of the dielectric film IL2, a wet cleaning treatment can be performed instead of the plasma cleaning treatment. In the wet cleaning treatment, a chemical solution effective for removing carbon adhering to the upper surface of the dielectric film IL2 is used. Specifically, a wet cleaning treatment using SPM (Sulfuric acid-hydrogen Peroxide Mixture), APM (Ammonia-hydrogen Peroxide Mixture) or ozonated water can be used. After removing the carbon (C) adhering to the upper surface of the dielectric film IL2 by the wet cleaning treatment, by forming the material layer MTa on the dielectric film IL2, the fluctuation of the carbon (C) content and the temperature coefficient of resistance of the resistor element RS can be suppressed. Also, by properly managing the time from the wet cleaning treatment to the formation of the material layer MTa, the re-adhesion of carbon (C) to the upper surface of the dielectric film IL2 can be suppressed.

However, when the plasma cleaning treatment is used as the cleaning treatment for the upper surface of the dielectric film IL2, after the plasma cleaning treatment, the film formation step of the material layer MTa can be performed continuously without exposing the semiconductor substrate SB to the atmosphere. Therefore, after the cleaning treatment and before the film formation step of the material layer MTa, it is possible to prevent carbon (C) from re-adhering to the upper surface of the dielectric film IL2.

The invention made by the present inventor has been described above in detail based on the embodiment, but the present invention is not limited to the embodiment described above, and it is needless to say that various modifications can be made without departing from the gist thereof.

What is claimed is:

1. A semiconductor device comprising:
a first dielectric film;
a resistor element disposed on the first dielectric film, the resistor element containing silicon, chromium, and carbon; and
a second dielectric film disposed on the resistor element so as to contact the resistor element,
wherein a silicon concentration of the resistor element increases from a center part of the resistor element towards an upper surface of the resistor element, and increases from the center part of the resistor element towards a lower surface of the resistor element.

2. The semiconductor device according to claim 1,
wherein a chromium concentration of the resistor element decreases from the center part of the resistor element towards the upper surface of the resistor element, and decreases from the center part of the resistor element towards the lower surface of the resistor element.

3. The semiconductor device according to claim 2,
wherein a carbon concentration of the resistor element increases from the center part of the resistor element towards the upper surface of the resistor element, and increases from the center part of the resistor element towards the lower surface of the resistor element.

4. The semiconductor device according to claim 1,
wherein a thickness of the resistor element is 10 nm or less.

5. The semiconductor device according to claim 4,
wherein a ratio of silicon to chromium is greater than 2,and
wherein a carbon content in the resistor element is 15atomic percent or more and 30 atomic percent or less.

6. The semiconductor device according to claim 4,
wherein a width of the resistor element is 10 nm or more and 40 nm or less.

7. The semiconductor device according to claim 4,
wherein a width of the resistor element is 10 nm or less.

8. The semiconductor device according to claim 7,
wherein each of the upper surface and the lower surface of the resistor element has a plurality of protrusions.

9. The semiconductor device according to claim 1,
wherein in the resistor element, a silicon concentration in a region close to a side surface of the resistor element is higher than a silicon concentration in the center part of the resistor element.

10. The semiconductor device according to claim 9,
wherein in the resistor element, a chromium concentration in the region close to the side surface of the resistor element is lower than a chromium concentration in the center part of the resistor element, and
wherein in the resistor element, a carbon concentration in the region close to the side surface of the resistor element is higher than a carbon concentration in the center part of the resistor element.

11. The semiconductor device according to claim 1, comprising:
a first wiring disposed so as to be covered by the first dielectric film;
a second wiring disposed so as to be covered by the first dielectric film;
a first plug disposed in the first dielectric film and connected to the first wiring; and
a second plug disposed in the first dielectric film and connected to the second wiring,
wherein the resistor element connects the first plug and the second plug.

12. A method of manufacturing a semiconductor device, the method comprising:
(a) forming a first dielectric film;
(b) forming a resistor element on the first dielectric film, the resistor element containing silicon, chromium, and carbon;
(c) forming a second dielectric film on the first dielectric film so as to cover the resistor element and contact the resistor element; and
(d) after the (c), performing an annealing treatment on the resistor element in a state where the second dielectric film is disposed on the resistor element,
wherein a silicon concentration of the resistor element after the (d) increases from a center part of the resistor element towards an upper surface of the resistor element, and increases from the center part of the resistor element towards a lower surface of the resistor element.

13. The method according to claim 12,
wherein the (b) comprises:
(b1) forming a first film on the first dielectric film, the first film containing silicon, chromium, and carbon; and
(b2) after the (b1), patterning the first film to form the resistor element.

14. The method according to claim 12,
wherein a temperature of the annealing treatment is 300degrees Celsius or more and 500 degrees Celsius or less.

15. The method according to claim 12, comprising:
(a1) after the (a) and before the (b), performing a plasma treatment on an upper surface of the first dielectric film.

16. The method according to claim 12, comprising:
(a1) after the (a) and before the (b), cleaning an upper surface of the first dielectric film using SPM, APM or ozonated water.

17. The method according to claim 12,
wherein a thickness of the resistor element is 10 nm or less.

18. The method according to claim 12,
wherein a chromium concentration of the resistor element after the (d) decreases from the center part of the resistor element towards the upper surface of the resistor element, and decreases from the center part of the resistor element towards the lower surface of the resistor element.

19. The method according to claim 12,
wherein a carbon concentration of the resistor element after the (d) increases from the center part of the resistor element towards the upper surface of the resistor element, and increases from the center part of the resistor element towards the lower surface of the resistor element.

20. A method of manufacturing a semiconductor device, the method comprising:
(a) forming a first dielectric film;
(b) forming a first film on the first dielectric film, the first film containing silicon, chromium, and carbon;
(c) forming a second dielectric film on the first film so as to contact the first film;
(d) after the (c), patterning the second dielectric film and the first film to form a resistor element from the patterned first film; and
(e) after the (c), performing an annealing treatment on the first film or on the resistor element in a state where the second dielectric film is disposed on the first film or on the resistor element,
wherein a silicon concentration of the resistor element after the (c) increases from a center part of the resistor element towards an upper surface of the resistor element, and increases from the center part of the resistor element towards a lower surface of the resistor element.
